(19) United States
(12) Patent Application Publication
(10) Pub. No.: US 2023/0111608 A1
(43) Pub. Date: Apr. 13, 2023

(54) PHOTOMASK INCLUDING PELLICLE

(71) Applicant: SK hynix Inc., Icheon-si Gyeonggi-do (KR)

(72) Inventor: Tae Joong HA, Icheon-si Gyeonggi-do (KR)

(73) Assignee: SK hynix Inc., Icheon-si Gyeonggi-do (KR)

(21) Appl. No.: 17/704,548

(22) Filed: Mar. 25, 2022

(30) Foreign Application Priority Data
Oct. 7, 2021 (KR) 10-2021-0133506

(51) Int. Cl. G03F 1/64; C01B 32/159; G03F 7/20

(52) U.S. Cl. CPC G03F 1/64; C01B 32/159; G03F 7/70983; G03F 7/70958

(57) ABSTRACT

There is provided a photomask including a pellicle. The photomask may include a substrate and a pellicle, and mask patterns may be disposed on the substrate. The pellicle may include a carbon nanotube membrane providing a plurality of pores. The pellicle may include a coating layer on the carbon nanotube membrane.

### CROSS-REFERENCE TO RELATED APPLICATIONS

The present application claims priority under 35 U.S.C 119(a) to Korean Application No. 10-2021-0133506, filed on Oct. 7, 2021, which is incorporated herein by reference in its entirety.

### BACKGROUND

### 1. Technical Field

The present disclosure generally relates to a lithography technology, and more particularly, to a photomask including a pellicle.

### 2. Related Art

The lithography technology is being used to implement patterns constituting an integrated circuit on a wafer or semiconductor substrate. As the size or line width or critical dimension (CD) of the patterns constituting the integrated circuit decreases, the lithography technology is being improved to use a shorter wavelength band of exposure light sources. In the lithography technology, an argon fluoride (ArF) light source in a wavelength band of 193 nm is employed as an exposure light source. A photomask may be configured to provide a pattern image to be transferred onto the wafer. The photomask may be used in the form of an assembly in which a pellicle is assembled on a mask substrate. The pellicle may serve to protect patterns to be transferred formed on a photomask or a substrate. As the pellicle is assembled and introduced onto the photomask, contamination such as haze may be induced in the photomask and a technique for improving contamination or haze is required.

### SUMMARY

An embodiment of the present disclosure may provide a photomask including a substrate on which mask patterns are disposed, and a pellicle located over the substrate, wherein the pellicle may include a carbon nanotube membrane providing a plurality of pores and a coating layer including polymers on the carbon nanotube membrane.

Another embodiment of the present disclosure may provide a photomask including a substrate on which mask patterns are disposed, and a pellicle located over the substrate, wherein the pellicle may include a carbon nanotubes disposed to provide interspaces as pores, and a coating layer on the carbon nanotubes.

### BRIEF DESCRIPTION OF THE DRAWINGS

FIG. 1 is a schematic cross-sectional view illustrating a photomask according to an embodiment of the present disclosure.

FIGS. 2, 3 and 4 are schematic views illustrating a carbon nanotube membrane of the photomask of FIG. 1.

FIGS. 5, 6, 7, 8, and 9 are schematic views illustrating pellicles of the photomask of FIG. 1.

FIG. 10 is a schematic view illustrating that hazes are generated in a photomask according to a comparative example.

FIG. 11 is a schematic view illustrating that deformation occurs in a pellicle of a photomask according to a comparative example.

FIGS. 12, 13, 14, 15, 16, 17, 18, 19, 20, 21, and 22 are schematic cross-sectional views illustrating photomasks according to other embodiments.

### DETAILED DESCRIPTION

The terms used herein may correspond to words selected in consideration of their functions in presented embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms “first” and “second,” “side,” “top,” and “bottom or lower” may be used herein to describe various devices, these devices should not be limited by these terms. These terms are only used to distinguish one device from another device, but not used to indicate a particular sequence or number of devices.

Embodiments of the present disclosure may be applied to a technical field that implements integrated circuits such as a DRAM device, a PCRAM device, or a ReRAM device. In addition, embodiments of the present disclosure may also be applied to a technology field for implementing a memory device such as SRAM, FLASH, MRAM, or FeRAM, or a logic device in which a logic integrated circuit is integrated. Embodiments of the present disclosure may be applied to the technical field of implementing various products requiring fine patterns.

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

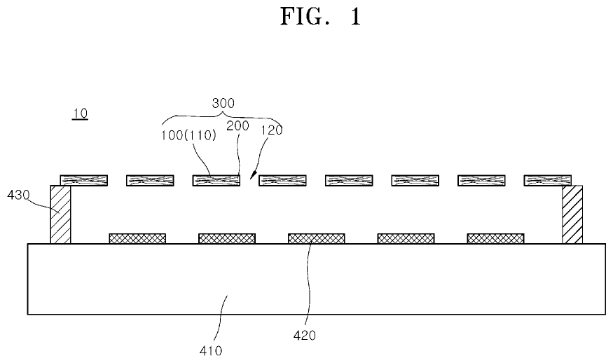

FIG. 1 is a schematic cross-sectional view illustrating a cross-sectional shape of a photomask 10 according to an embodiment of the present disclosure.

Referring to FIG. 1, the photomask 10 may include a substrate 410 and a pellicle 300. The pellicle 300 may be assembled on the substrate 410 with a frame 430. The frame 430 may be formed to support the pellicle 300 on the substrate 410. The frame 430 may be adhered to the substrate 410 by an adhesive layer (not shown). The pellicle 300 may be adhered to the frame 430 with another adhesive layer (not shown).

The substrate 410 may include a material that transmits exposure light used in a lithography process. The light source providing the exposure light may be composed of an argon fluoride (ArF) light source. The argon fluoride (ArF) light source may provide exposure light having a wavelength band of approximately 193 nm to the substrate 410. The substrate 410 may include a material through which exposure light having a wavelength band of 193 nm passes. The substrate 410 may include quartz. As such, the photomask 10 may have a transmission type mask structure including the substrate 410 through which exposure light passes.

Mask patterns 420 may be disposed on the substrate 410. The mask pattern 420 may have a pattern shape to be image-transferred to a wafer (not shown) or a semiconductor substrate (not shown) through a lithography process. The mask pattern 420 may include a light blocking layer that blocks the exposure light that has passed through the substrate 410. The light blocking layer may include a chromium (Cr) layer. As such, the photomask 10 may have a binary mask structure. In another embodiment, the mask pattern 420 may include a phase shifter that shifts a phase of the exposure light that transmitted through the substrate 410. The phase shifter may include a material that shifts the phase of the exposure light transmitted through the substrate 410, such as molybdenum silicon oxynitride (MoSiON). As such, the photomask 10 may have a phase shift mask structure.

The pellicle 300 may include a carbon nanotube membrane 100 and a coating layer 200. The carbon nanotube membrane 100 may include a film including carbon nanotubes 110. The carbon nanotube membrane 100 may provide a plurality of pores 120. The pores 120 of the carbon nanotube membrane 100 may be open pores that substantially vertically penetrate the pellicle 300. In another embodiment, the pores 120 may be provided as interspaces between the carbon nanotubes entangled with each other, the carbon nanotubes included in the carbon nanotube membrane 100.

The coating layer 200 may be formed by coating polymers on the carbon nanotube membrane 100. The coating layer 200 may be formed such that the pores 120 of the carbon nanotube membrane 100 are maintained as open pores that substantially vertically penetrate the pellicle 300. The polymers constituting the coating layer 200 may include polymers known to constitute a pellicle for an ArF light source. The coating layer 200 may include fluoropolymers. The fluoropolymers may be polymers having a plurality of carbon-fluorine bonds. The coating layer 200 may include celluloses.

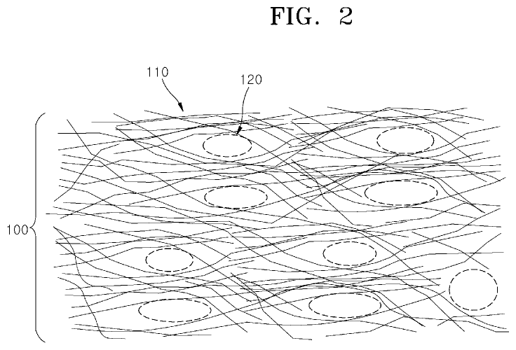

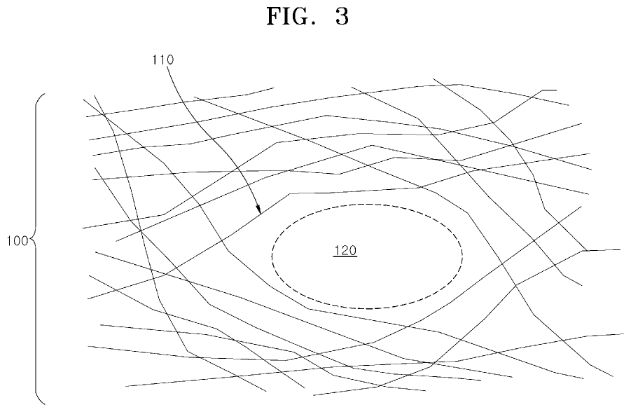

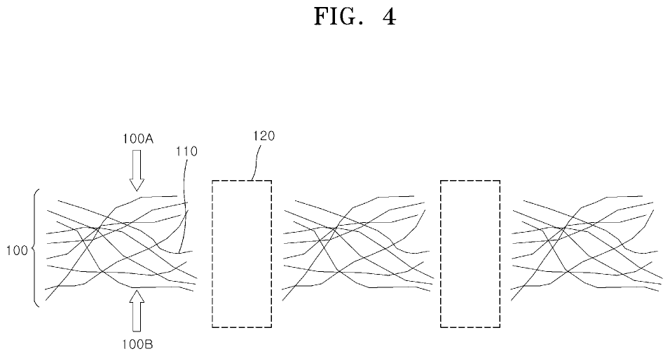

FIG. 2 is a schematic plan view illustrating the carbon nanotube membrane 100 of the photomask 10 of FIG. 1. FIG. 3 is a schematic plan view illustrating an enlarged portion of the pore 120 of the carbon nanotube membrane 100 of FIG. 2. FIG. 4 is a schematic cross-sectional view illustrating the carbon nanotube membrane 100 of the photomask 10 of FIG. 1.

Referring to FIG. 2, the carbon nanotubes 110 may overlap with each other, the carbon nanotubes 110 may be entangled with each other, some portions of the carbon nanotubes 110 may directly contact each other, or some portions of the carbon nanotubes 110 may be joined to each other, thereby forming a layer of carbon nanotubes. The carbon nanotubes 110 may be connected to each other while forming a network by the van der Waals force. In order to form a layer of carbon nanotubes 110, the carbon nanotubes 110 may be processed to form a layer by pressing the carbon nanotubes 110 while the carbon nanotubes 110 are overlapped with each other.

Referring to FIGS. 2 and 3, as the carbon nanotubes 110 overlap and contact each other or become entangled with each other, separation spaces formed between the neighboring carbon nanotubes 110 may provide the pores 120 of the carbon nanotube membrane 100. The size of the pore 120 of the carbon nanotube membrane 100 may be determined by a separation spacing between the carbon nanotubes 110. The separation spacing between the carbon nanotubes 110 or the size of the pore 120 of the carbon nanotube membrane 100 may be in a range of several nm (nanometers) to several hundred nm. The pore 120 of the carbon nanotube membrane 100 may have a size or diameter of approximately 5 nm to 200 nm. According to the density of the carbon nanotubes 110 constituting the carbon nanotube membrane 100, the average size of the pores 120 of the carbon nanotube membrane 100 may be adjusted differently.

Referring to FIGS. 3 and 4, the pores 120 of the carbon nanotube membrane 100 may be open pores that substantially vertically penetrate the carbon nanotube membrane 100. The pores 120 of the carbon nanotube membrane 100 may be open pores extending from an upper surface 100A of the carbon nanotube membrane 100 to a bottom surface 100B opposite to the upper surface 100A. The bottom surface 100B of the carbon nanotube membrane 100 may be a surface of the carbon nanotube membrane 100, facing the substrate (410 of FIG. 1) of the photomask (10 of FIG. 1).

Referring to FIG. 4, the carbon nanotube membrane 100 may be formed to have a thickness of approximately 5 nm to 1000 nm. The carbon nanotube membrane 100 may be formed to have a thickness of several nm to several hundred nm. The carbon nanotube membrane 100 may be formed to have a thickness of approximately 5 nm to 280 nm. The carbon nanotube membrane 100 may be formed to have a thickness of several nm. The carbon nanotube membrane 100 may be formed to have a thickness of approximately 5 nm to 10 nm.

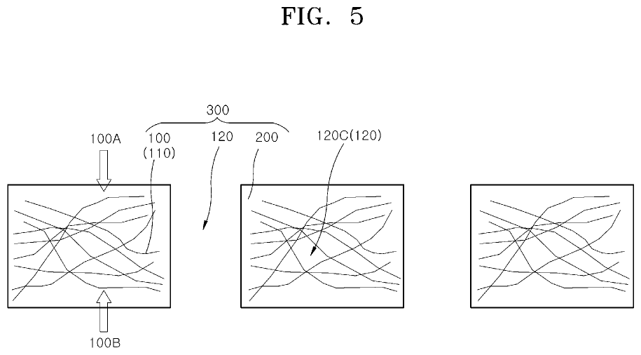

FIG. 5 is a schematic cross-sectional view illustrating the pellicle 300 of the photomask 10 of FIG. 1.

Referring to FIGS. 5 and 1, the coating layer 200 may coat the carbon nanotube membrane 100. The coating layer 200 may coat the carbon nanotubes 110 constituting the carbon nanotube membrane 100. The coating layer 200 may extend to cover the upper surface 100A and the bottom surface 100B of the carbon nanotube membrane 100. The coating layer 200 may open some pores 120 of the carbon nanotube membrane 100 to maintain them as open pores and may fill the other pores 120C to convert them into closed pores. The pores 120C having a relatively small size may be filled with the coating layer 200. However, the pores 120 having a relatively large size might not be filled by the coating layer 200 and maintain open states, thereby substantially penetrating the carbon nanotube membrane 100.

The coating layer 200 may be formed by coating a coating solution on the carbon nanotube membrane 100. The coating solution may be formed by dissolving or dispersing polymers such as fluoropolymers or celluloses in a solvent. The coating layer 200 may be formed by coating the coating solution on the upper surface 100A or the bottom surface 100B of the carbon nanotube membrane 100 by a spin coating method. The coating solution may be coated on the upper surface 100A or the bottom surface 100B of the carbon nanotube membrane 100 by a spray method to form the coating layer 200. The coating layer 200 may be formed on the upper surface 100A or the bottom surface 100B of the carbon nanotube membrane 100 by dipping the carbon nanotube membrane 100 in the coating solution. The coating layer 200 may be formed by applying the coating solution on the upper surface 100A or the bottom surface 100B of the carbon nanotube membrane 100 and heating the applied coating solution to remove the solvent.

The coating layer 200 may have a light transmittance of about 95% or more with respect to exposure light in a wavelength band of 193 nm. The light transmittance may depend on the thickness of the coating layer 200 and may decrease as the thickness increases. The coating layer 200 may be formed to have a thickness of approximately 5 nm to 280 nm. Since the coating layer 200 including the fluoropolymers has a light transmittance of at least 99% with respect to the exposure light in the 193 nm wavelength band at a thickness of 280 nm, the coating layer 200 including the fluoropolymers may be formed to have a thickness of approximately 5 nm to 280 nm.

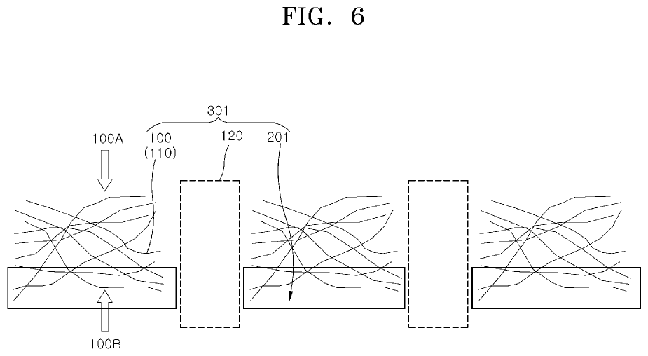

FIG. 6 is a schematic cross-sectional view illustrating a pellicle 301 of the photomask of FIG. 1 according to another embodiment of the present disclosure.

Referring to FIGS. 6 and 1, the pellicle 301 of the photomask 10 may include a coating layer 201 formed on the bottom surface 100B of the carbon nanotube membrane 100. The coating layer 201 might not extend on the upper surface 100A of the carbon nanotube membrane 100. The coating layer 201 may be selectively formed only on the bottom surface 100B of the carbon nanotube membrane 100 by coating a coating solution on the bottom surface 100B of the carbon nanotube membrane 100 in a spray method or coating the coating solution on the bottom surface 100B of the carbon nanotube membrane 100 in a spin coating method.

Because the coating layer 201 is limitedly formed only on the bottom surface 100B of the carbon nanotube membrane 100, only some carbon nanotubes 110 positioned on the bottom surface 100B of the carbon nanotube membrane 100 or positioned over the bottom surface 100B of the carbon nanotube membrane 100 may be coated by the coating layer 201. Accordingly, in some embodiments, the possibility that the pores 120 of the carbon nanotube membrane 100 are filled and closed by the coating layer 201 may be reduced. In some embodiments, the pellicle 301 may secure a relatively larger number of open pores 120 rather than a case in which the coating layer (300 in FIG. 5) is formed to cover the upper surface 100A and the bottom surface 100B of the carbon nanotube membrane 100.

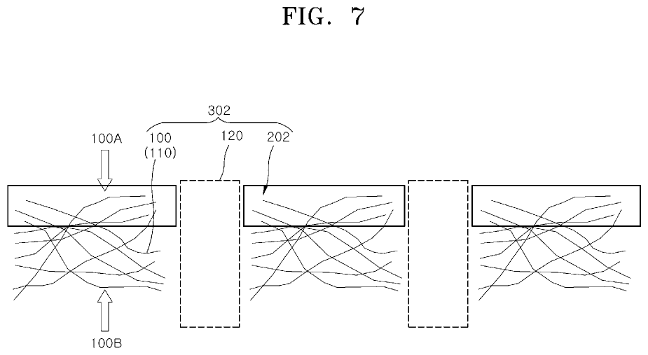

FIG. 7 is a schematic cross-sectional view illustrating a pellicle 302 of the photomask of FIG. 1 according to another embodiment of the present disclosure.

Referring to FIGS. 7 and 1, the pellicle 302 of the photomask 10 may include a coating layer 202 formed on the upper surface 100A of the carbon nanotube membrane 100. The coating layer 202 might not extend on the bottom surface 100B of the carbon nanotube membrane 100. The coating layer 202 may be selectively formed only on the upper surface 100A of the carbon nanotube membrane 100 by coating a coating solution on the upper surface 100A of the carbon nanotube membrane 100 in a spray method or coating the coating solution on the upper surface 100A of the carbon nanotube membrane 100 in a spin coating method.

Because the coating layer 202 is limitedly formed only on the upper surface 100A of the carbon nanotube membrane 100, only some carbon nanotubes 110 positioned on the upper surface 100A of the carbon nanotube membrane 100 or positioned under the upper surface 100A may be coated with the coating layer 202. Accordingly, in an embodiment, the possibility that the pores 120 of the carbon nanotube membrane 100 are filled and closed by the coating layer 201 may be reduced. In some embodiments, the pellicle 302 may secure a relatively larger number of open pores 120 rather than a case in which the coating layer (300 in FIG. 5) is formed to cover the upper surface 100A and the bottom surface 100B of the carbon nanotube membrane 100.

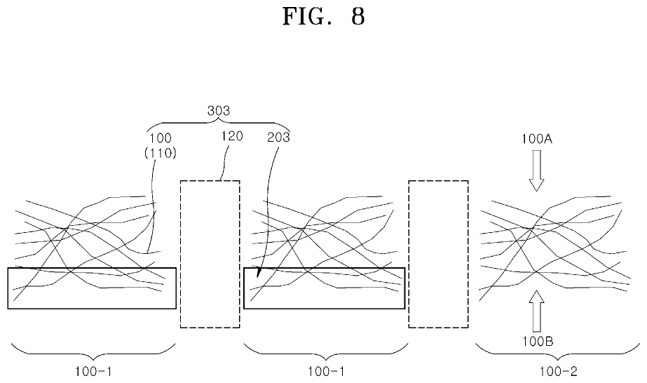

FIG. 8 is a schematic cross-sectional view illustrating a pellicle 303 of the photomask 10 of FIG. 1 according to another embodiment of the present disclosure.

Referring to FIGS. 8 and 1, the pellicle 303 of the photomask 10 may include a coating layer 203 selectively formed only in some regions 100-1 of the bottom surface 100B of the carbon nanotube membrane 100. The coating layer 203 may be limitedly formed to cover only some regions 100-1 of the bottom surface 100B of the carbon nanotube membrane 100. The coating layer 203 might not extend to other partial regions 100-2 of the bottom surface 100B of the carbon nanotube membrane 100, so that the coating layer 203 may be formed to open other partial regions 100-2 of the bottom surface 100B of the carbon nanotube membrane 100.

The coating solution may be limitedly applied to only some regions 100-1 of the bottom surface 100B of the carbon nanotube membrane 100 and heated to form the coating layer 203. The limited application of the coating solution may be performed by using a spray method. Since the coating layer 203 is limitedly formed only in some regions 100-1 of the bottom surface 100B of the carbon nanotube membrane 100, only some carbon nanotubes 110 positioned in some regions 100-1 of the bottom surface 100B or positioned over some regions 100-1 of the bottom surface 100B may be coated with the coating layer 203. Accordingly, in an embodiment, the possibility that the pores 120 of the carbon nanotube membrane 100 are filled and closed by the coating layer 203 may be relatively lower. Thus, in some embodiments, because other partial regions 100-2 of the bottom surface 100B of the carbon nanotube membrane 100 are not coated with the coating layer 203, the pellicle 303 may ensure a relatively larger number of open pores 120.

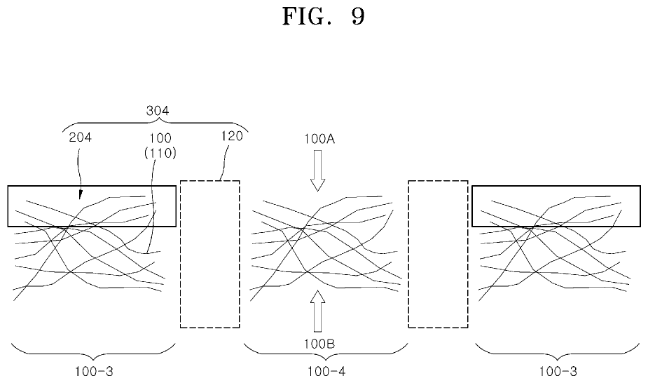

FIG. 9 is a schematic cross-sectional view illustrating a pellicle 304 of the photomask 10 of FIG. 1 according to another embodiment of the present disclosure.

Referring to FIGS. 9 and 1, the pellicle 304 of the photomask 10 may include a coating layer 204 selectively formed only in some regions 100-3 of the upper surface 100A of the carbon nanotube membrane 100. The coating layer 204 may be limitedly formed to cover only some regions 100-3 of the upper surface 100A of the carbon nanotube membrane 100. The coating layer 204 might not extend to other partial regions 100-4 of the upper surface 100A of the carbon nano tube membrane 100 to be formed to open other partial regions 100-4 of the upper surface 100A of the carbon nanotube membrane 100. Accordingly, in some embodiments, the pellicle 303 may secure a relatively larger number of open pores 120.

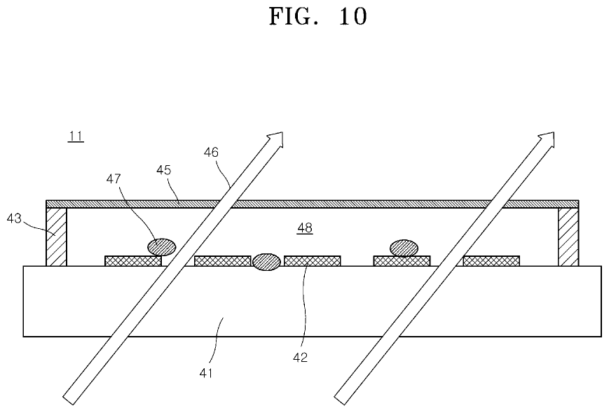

FIG. 10 is a schematic view illustrating that hazes 47 are generated in a photomask 11 according to a comparative example.

Referring to FIG. 10, the photomask 11 according the comparative example may include a structure in which a pellicle 45 is attached to a substrate 41 on which mask patterns 42 are formed by a frame 43. An inner space 48 of the photomask 11 may be sealed by the pellicle 45, the substrate 41, and the frame 43. As exposure light 46 is incident onto the photomask 11, various ionic components may be generated from components constituting the pellicle 45 or the frame 43. The ionic components may include ions of sulfur oxide (SOx), nitrogen oxide (NOx), ammonia (NH4), or phosphate (PO4). These ionic components may be trapped in the inner space 48 of the photomask 11 and act as a cause of contamination such as haze in the inner space 48. Since the inner space 48 is sealed, foreign substances such as haze may contaminate a surface of the substrate 41 or the mask patterns 42.

The photomask 10 shown in FIG. 1 may include one of the pellicles 300, 301, 302, 303, and 304 providing pores 120 as shown in FIGS. 5 to 9, the ionic components may be emitted to the outside of the photomask 10 through the pores 120. Accordingly, in some embodiments, the generation of the foreign substances such as haze or contamination by the foreign substances in the photomask 10 may be reduced.

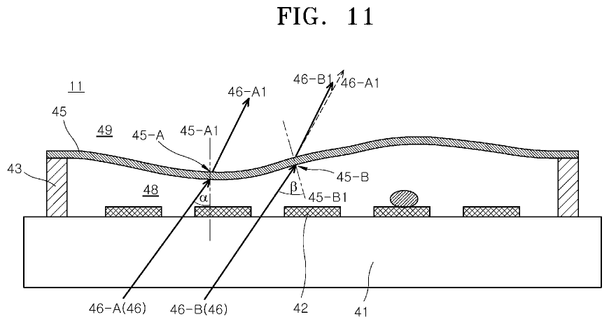

FIG. 11 is a schematic view illustrating that deformation occurs in the pellicle 45 of the photomask 11 according to the comparative example.

Referring to FIG. 11, in the photomask 11 according to the comparative example, as the exposure light 46 is incident onto the photomask 11, a pressure gradient may be generated in the inner space 48. Since the inner space 48 may be sealed by the pellicle 45, the substrate 41, and the frame 43, as the photomask 11 scan-moves with respect to the exposure light 46 in the exposure apparatus, the pellicle 45 may be deformed by a pressure difference between the inner space 48 and an outer space 49 of the photomask 11. When the pellicle 45 is deformed, the paths of the emitted exposure lights 46-A1 and 46-B1 may be different depending on the position of the pellicle 45.

The first exposure light 46-A and the second exposure light 46-B incident on the substrate 41 may be emitted at a first position 45-A and at a second position 45-B of the pellicle 45 deformed in different directions, respectively. The first exposure light 46-A1 emitted at the first position 45-A of the pellicle 45 and the second exposure light 46-B1 emitted at the second position 45-B of the pellicle 45 may proceed in different directions. Because the pellicle 45 is deformed, a surface direction 45-A1 of the pellicle 45 at the first position 45-A may differ from a surface direction 45-B1 of the pellicle 45 at the second position 45-B. Accordingly, the first angle α at which the first exposure light 46-A is incident on the pellicle 45 and the second angle θ at which the second exposure light 46-B is incident on the pellicle 45 may be different from each other. Accordingly, the direction directions in which the first exposure light 46-A1 and the second exposure light 46-B1 emitted from the pellicle 45 are refracted may be different from each other. As described, in an embodiment, when the direction in which the exposure light 46 is refracted and emitted is changed due to the deformation of the pellicle 45, the position of the wafer (not shown) to which the exposure light 46 reaches may be shifted, and the position shift may degrade overlays between patterns.

The photomask 10 shown in FIG. 1 may include one of the pellicles 300, 301, 302, 303, and 304 providing pores 120 as shown in FIGS. 5 to 9, so that the inside of the photomask 10 may be connected to the outside through the pores 120. In some embodiments, since the air may freely move through the pores 120, pressure equilibrium between the inside and outside of the photomask 10 may be maintained. Accordingly, in some embodiments, it is possible to substantially prevent or reduce the occurrence of a pressure gradient inside the photomask 10. Accordingly, in some embodiments, it is possible to substantially prevent or reduce the deformation of the pellicles 300, 301, 302, 303, and 304 due to the pressure difference or pressure gradient. Thus, in some embodiments, it is possible to substantially prevent or reduce the degradation of the overlay of the transferred patterns according to the deformation of the pellicle (45 of FIG. 10).

Referring again to FIG. 1, in an embodiment, by forming the coating layer 200 of the photomask 10 in the carbon nanotube membrane 100, the carbon nanotube membrane 100 may include the open pores 120 while securing durability and strength of the pellicle 300. In some embodiments, the coating layer 200 may serve as a reinforcement layer for reinforcing the carbon nanotube membrane 100, so that the carbon nanotube membrane 100 may have a relatively thin thickness. In addition, in some embodiments, the carbon nanotube membrane 100 may be composed of carbon nanotubes 110 having a relatively low density, so that the carbon nanotube membrane 100 may secure the pores 120 with a relatively higher density or may secure a relatively larger number of pores 120. Accordingly, in some embodiments, the generation of contaminants such as haze in the photomask 10 may be reduced. In addition, in some embodiments, deformation of the pellicle 300 may be substantially prevented.

The coating layer 200 may reinforce the carbon nanotube membrane 100, so that the carbon nanotube membrane 100 may be implemented to have a thinner thickness. The carbon nanotube membrane 100 may be implemented with a thickness of several nm or a thickness of 5 nm to 10 nm. The light transmittance of the pellicle 300 may depend on the thickness of the pellicle 300. In some embodiments, since the carbon nanotube membrane 100 may be implemented to have such a thin thickness, the light transmittance of the pellicle 300 may be improved. It is possible to implement the pellicle 300 having a light transmittance of at least 90% or more with respect to a 193 nm light source.

As described, when the carbon nanotube membrane 100 is configured to have a thin thickness, the possibility that the carbon nanotube membrane 100 is damaged and broken may be relatively increased. However, even if the carbon nanotube membrane 100 is broken, the coating layer 200 may hold fragments of the damaged carbon nanotube membrane 100. Accordingly, in some embodiments, it is possible to substantially prevent or reduce the contamination of the photomask 10 by fragments of the broken carbon nanotube membrane 100.

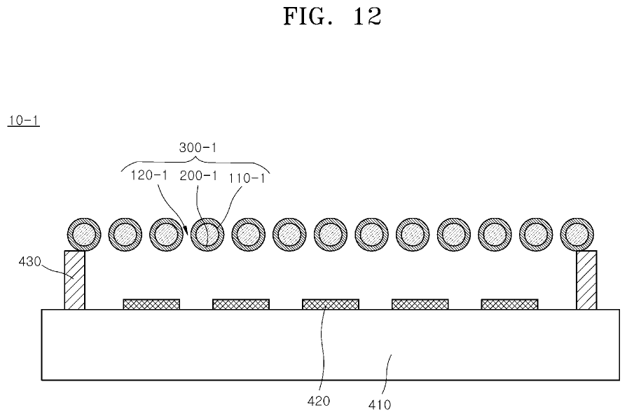

FIGS. 12 to 22 are schematic cross-sectional views illustrating photomasks according to other embodiments. In FIGS. 12 to 22, elements indicated by the same reference numerals as in FIG. 1 may be substantially the same elements.

FIG. 12 schematically illustrates a cross-sectional shape of a photomask 10-1 according to another embodiment of the present disclosure. The photomask 10-1 may include a substrate 410 and a pellicle 300-1. The substrate 410 may include mask patterns 420. A frame 430 may assemble the pellicle 300-1 to the substrate 410. The pellicle 300-1 may include carbon nanotubes 110-1 and a coating layer 200-1.

The carbon nanotubes 110-1 may be spaced apart from each other in the lateral direction, and separation spaces between the neighboring carbon nanotubes 110-1 may be provided as pores 120-1. The carbon nanotubes 110-1 may be disposed to be substantially spaced apart from each other one by one in the lateral direction. As shown in FIG. 2, the carbon nanotubes (110 of FIG. 2) may form a network in bundles with each other and may be tangled with each other to form a layer of carbon nanotubes, but may implement a layer shape in which the carbon nanotubes 110-1 are arranged substantially spaced apart from each other in the lateral direction, as shown in FIG. 12, by making the density of the carbon nanotubes (110 in FIG. 2) relatively lower and inducing the thickness of the layer of carbon nanotubes to be relatively thinner. The layer of carbon nanotubes 110-1 may be a layer in which the carbon nanotubes are dispersed as a substantially single layer.

In some embodiments, the coating layer 200-1 may be formed to surround or substantially surround each of the carbon nanotubes 110-1. In other embodiments, the coating layer 200-1 may be formed to completely surround each of the carbon nanotubes 110-1 by surrounding each of the carbon nanotubes 110-1 continuously without gaps. The coating layer 200-1 may coat the carbon nanotubes 110-1 to bind them to be maintained as a single layer. The coating layer 200-1 may be formed to coat the carbon nanotubes 110-1 while maintaining the pores 120-1.

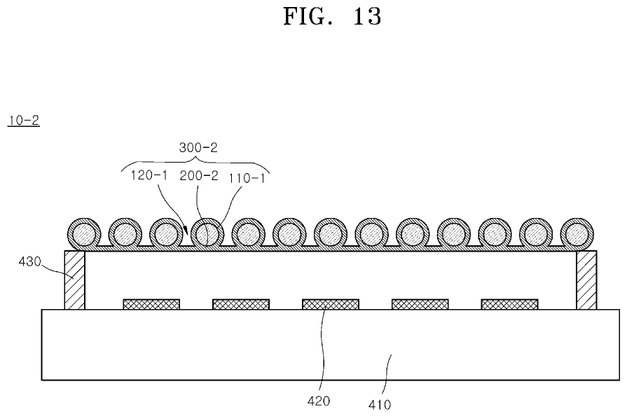

FIG. 13 schematically illustrates a cross-sectional shape of a photomask 10-2 according to another embodiment of the present disclosure. The photomask 10-2 may include a substrate 410 and a pellicle 300-2. The pellicle 300-2 may include carbon nanotubes 110-1 and a coating layer 200-2. In some embodiments, the coating layer 200-2 may be formed to surround or substantially surround each of the carbon nanotubes 110-1. In other embodiments, the coating layer 200-2 may be formed to completely surround each of the carbon nanotubes 110-1 by surrounding each of the carbon nanotubes 110-1 continuously without gaps. The coating layer 200-2 may extend while coating and binding the carbon nanotubes 110-1 to be maintained as a single layer. The coating layer 200-2 may extend while filling the pores 120-1. Some extending portions of the coating layer 200-2 may be formed or extended at a bottom portion of the pellicle 300-2 facing the substrate 410, as for example, illustrated in FIG. 13.

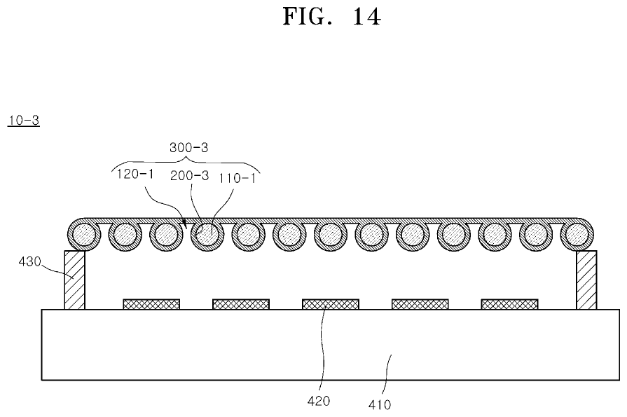

FIG. 14 schematically illustrates a cross-sectional shape of a photomask 10-3 according to another embodiment of the present disclosure. The photomask 10-3 may include a substrate 410 and a pellicle 300-3. The pellicle 300-3 may include carbon nanotubes 110-1 and a coating layer 200-3. In some embodiments, the coating layer 200-3 may be formed to surround or substantially surround each of the carbon nanotubes 110-1. In other embodiments, the coating layer 200-3 may be formed to completely surround each of the carbon nanotubes 110-1 by surrounding each of the carbon nanotubes 110-1 continuously without gaps. The coating layer 200-3 may extend while coating and binding the carbon nanotubes 110-1 to be maintained as a single layer. The coating layer 200-3 may extend while filling the pores 120-1. The extending portions of the coating layer 200-3 may be formed or extended at an upper portion of the pellicle 300-3 opposite to a bottom portion of the pellicle 300-3 facing the substrate 410, as for example, illustrated in FIG. 14.

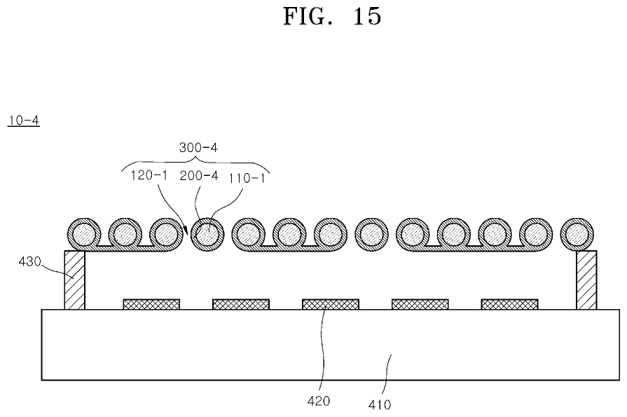

FIG. 15 schematically illustrates a cross-sectional shape of a photomask 10-4 according to another embodiment of the present disclosure. The photomask 10-4 may include a substrate 410 and a pellicle 300-4. The pellicle 300-4 may include carbon nanotubes 110-1 and a coating layer 200-4. In some embodiments, the coating layer 200-4 may be formed to surround or substantially surround each of the carbon nanotubes 110-1. In other embodiments, the coating layer 200-4 may be formed to completely surround each of the carbon nanotubes 110-1 by surrounding each of the carbon nanotubes 110-1 continuously without gaps. The coating layer 200-4 may extend while coating and binding the carbon nanotubes 110-1 to be maintained as a single layer. The coating layer 200-4 may extend while filling some of the pores 120-1 and may extend while leaving open the other of the pores 120-1. The extending portions of the coating layer 200-4 may be formed or extended at a bottom portion of the pellicle 300-4 facing the substrate 410, as for example, shown in FIG. 15.

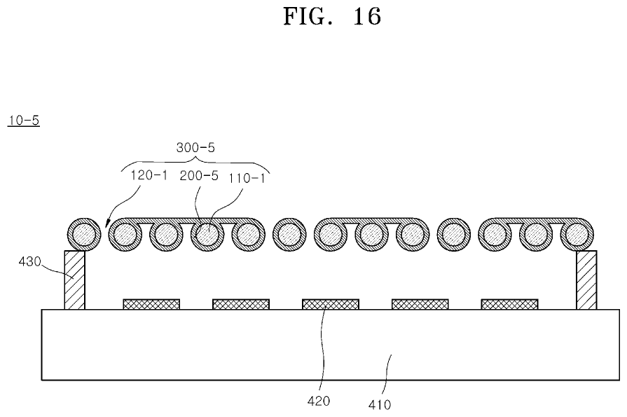

FIG. 16 schematically illustrates a cross-sectional shape of a photomask 10-5 according to another embodiment of the present disclosure. The photomask 10-5 may include a substrate 410 and a pellicle 300-5. The pellicle 300-5 may include carbon nanotubes 110-1 and a coating layer 200-5. In some embodiments, the coating layer 200-5 may be formed to surround or substantially surround each of the carbon nanotubes 110-1. In other embodiments, the coating layer 200-5 may be formed to completely surround each of the carbon nanotubes 110-1 by surrounding each of the carbon nanotubes 110-1 continuously without gaps. The coating layer 200-5 may extend while coating and binding the carbon nanotubes 110-1 to be maintained as a single layer. The coating layer 200-5 may extend while filling some of the pores 120-1 and may extend while leaving open the other pores 120-1. The extending portions of the coating layer 200-5 may be formed or extended at an upper portion of the pellicle 300-5, as for example, shown in FIG. 16.

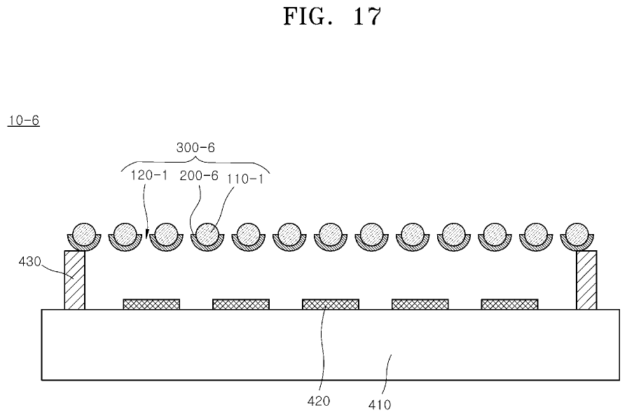

FIG. 17 schematically illustrates a cross-sectional shape of a photomask 10-6 according to another embodiment of the present disclosure. The photomask 10-6 may include a substrate 410 and a pellicle 300-6. The pellicle 300-6 may include carbon nanotubes 110-1 and a coating layer 200-6. The coating layer 200-6 may be formed to partially cover each of the carbon nanotubes 110-1. The coating layer 200-6 may extend while coating and binding the carbon nanotubes 110-1 to be maintained as a single layer. The coating layer 200-6 may extend while leaving open the pores 120-1. The coating layer 200-6 may be formed to cover a portion of each of the carbon nanotubes 110-1, positioned at a lower portion of the pellicle 300-6, as for example, shown in FIG. 17.

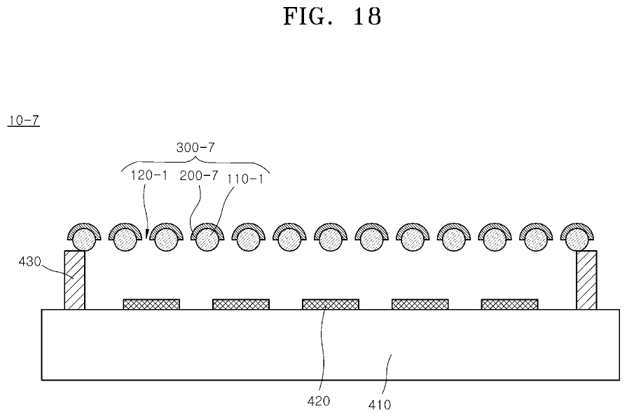

FIG. 18 schematically illustrates a cross-sectional shape of a photomask 10-7 according to another embodiment of the present disclosure. The photomask 10-7 may include a substrate 410 and a pellicle 300-7. The pellicle 300-7 may include carbon nanotubes 110-1 and a coating layer 200-7. The coating layer 200-7 may be formed to cover a portion of each of the carbon nanotubes 110-1, positioned at an upper portion of the pellicle 300-7, as for example, shown in FIG. 18.

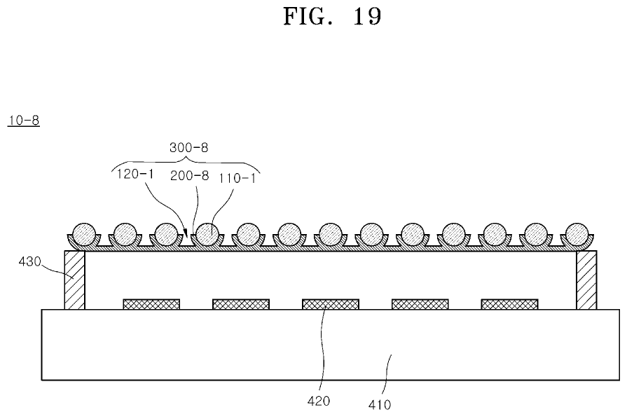

FIG. 19 schematically illustrates a cross-sectional shape of a photomask 10-8 according to another embodiment of the present disclosure. The photomask 10-8 may include a substrate 410 and a pellicle 300-8. The pellicle 300-8 may include carbon nanotubes 110-1 and a coating layer 200-8. The coating layer 200-8 may be formed to cover a portion of each of the carbon nanotubes 110-1, positioned at a lower portion of the pellicle 300-8, and the coating layer 200-8 may extend at the lower portion of the pellicle 300-8 while binding the carbon nanotubes 110-1 so that the pellicle 300-8 is maintained as a continuous layer.

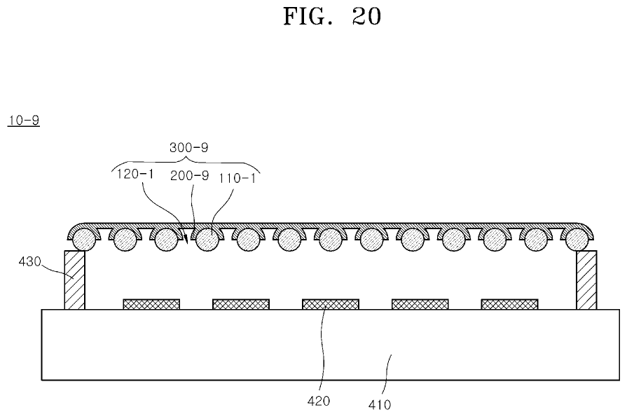

FIG. 20 schematically illustrates a cross-sectional shape of a photomask 10-9 according to another embodiment of the present disclosure. The photomask 10-9 may include a substrate 410 and a pellicle 300-9. The pellicle 300-9 may include carbon nanotubes 110-1 and a coating layer 200-9. The coating layer 200-9 may be formed to cover a portion of each of the carbon nanotubes 110-1, positioned at an upper portion of the pellicle 300-9, and the coating layer 200-9 may extend at the upper portion of the pellicle 300-9 while binding the carbon nanotubes 110-1 so that the pellicle 300-9 is maintained as a single layer.

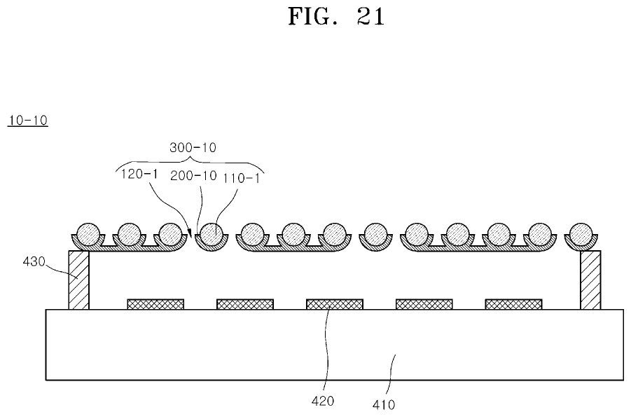

FIG. 21 schematically illustrates a cross-sectional shape of a photomask 10-10 according to another embodiment of the present disclosure. The photomask 10-10 may include a substrate 410 and a pellicle 300-10. The pellicle 300-10 may include carbon nanotubes 110-1 and a coating layer 200-10. The coating layer 200-10 may be formed to cover a portion of each of the carbon nanotubes 110-1, positioned at a lower portion of the pellicle 300-10, and the coating layer 200-10 may extend while leaving open some pores 120-1 at the lower portion of the pellicle 300-10, as for example, shown in FIG. 21.

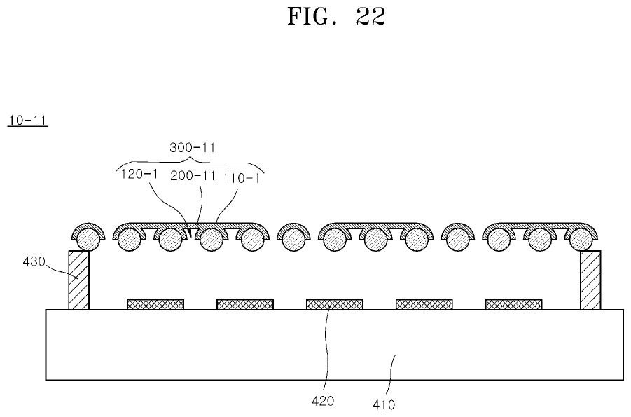

FIG. 22 schematically illustrates a cross-sectional shape of a photomask 10-11 according to another embodiment of the present disclosure. The photomask 10-11 may include a substrate 410 and a pellicle 300-11. The pellicle 300-11 may include carbon nanotubes 110-1 and a coating layer 200-11. The coating layer 200-11 may be formed to cover a portion of each of the carbon nanotubes 110-1, positioned at an upper portion of the pellicle 300-11, and the coating layer 200-11 may extend to open some of pores 120-1 at the upper portion of the pellicle 300-11, as for example, shown in FIG. 22.

The various concepts have been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the various concepts are not limited to the above descriptions but defined by the accompanying claims, and all of distinctive features in the equivalent scope should be construed as being included in the various concepts.

What is claimed is:

1. A photomask comprising:
a substrate;
mask patterns disposed on the substrate; and
a pellicle located over the substrate,
wherein the pellicle comprises:
a carbon nanotube membrane providing a plurality of pores; and
a coating layer including polymers on the carbon nanotube membrane.

2. The photomask of claim 1, wherein the coating layer is formed to fill less than all of the plurality of pores provided by the carbon nanotube membrane.

3. The photomask of claim 1, wherein the coating layer is formed to cover less than all regions of the carbon nanotube membrane.

4. The photomask of claim 1, wherein the coating layer is formed at a bottom surface of the carbon nanotube membrane, facing the substrate.

5. The photomask of claim 1, wherein the coating layer is formed at an upper surface of the carbon nanotube membrane, opposite to the bottom surface of the carbon nanotube membrane facing the substrate.

6. The photomask of claim 1, wherein the carbon nanotube membrane has a thickness of approximately 5 nm to 1000 nm.

7. The photomask of claim 1, wherein the carbon nanotube membrane has a thickness of approximately 5 nm to 280 nm.

8. The photomask of claim 1, wherein the carbon nanotube membrane has a thickness of approximately 5 nm to 100 nm.

9. The photomask of claim 1, wherein the carbon nanotube membrane has a thickness of approximately 5 nm to 10 nm.

10. The photomask of claim 1, wherein the carbon nanotube membrane includes carbon nanotubes, and
wherein the pores are provided as interspaces between the carbon nanotubes entangled with each other.

11. The photomask of claim 1, wherein the coating layer has a thickness of approximately 5 nm to 280 nm.

12. The photomask of claim 1, wherein the coating layer includes fluoropolymers.

13. The photomask of claim 1, wherein the coating layer includes celluloses.

14. The photomask of claim 12, wherein the coating layer has a light transmittance of approximately 95% or more with respect to exposure light in a wavelength band of 193 nm.

15. The photomask of claim 1, wherein the mask pattern includes a light blocking layer including chromium (Cr).

16. The photomask of claim 1, wherein the mask pattern includes a phase shifter including molybdenum silicon oxynitride (MoSiON).

17. The photomask of claim 1, further comprising a frame formed on the substrate and supporting the pellicle.

18. A photomask comprising:
a substrate;
mask patterns disposed on the substrate; and
a pellicle located over the substrate,
wherein the pellicle comprises:
carbon nanotubes disposed to provide interspaces as pores; and
a coating layer on the carbon nanotubes.

19. The photomask of claim 18, wherein the carbon nanotubes are disposed to be spaced apart from each other in the lateral direction.

20. The photomask of claim 18, wherein the coating layer is formed to surround at least one of the carbon nanotubes.

21. The photomask of claim 18, wherein the coating layer is formed to cover a portion of at least one of the carbon nanotubes.

22. The photomask of claim 18, wherein the coating layer extends and binds the carbon nanotubes to each other.

23. The photomask of claim 22, wherein the coating layer is extended filling less than all of the pores.

24. The photomask of claim 22, wherein the coating layer is formed at a bottom portion of the pellicle, facing the substrate.

25. The photomask of claim 22, wherein the coating layer is formed at an upper portion of the pellicle, opposite to the bottom portion of the pellicle facing the substrate.

26. The photomask of claim 18, wherein the coating layer includes fluoropolymers.

27. The photomask of claim 18, wherein the coating layer includes celluloses.
